(19) United States
(12) Patent Application Publication
(10) Pub. No.: US 2013/0082361 A1
(43) Pub. Date: Apr. 4, 2013

(54) MANUFACTURING METHOD FOR FLEXIBLE DEVICE AND FLEXIBLE DEVICE MANUFACTURED BY THE SAME

(71) Applicants: Keon Jae LEE, Daejeon (KR); Kwyro Lee, Daejeon (KR); Geon Tae Hwang, Busan (KR); Donggu Im, Daejeon (KR)

(72) Inventors: Keon Jae LEE, Daejeon (KR); Kwyro Lee, Daejeon (KR); Geon Tae Hwang, Busan (KR); Donggu Im, Daejeon (KR)

(21) Appl. No.: 13/396,302

(22) Filed: Feb. 14, 2012

(30) Foreign Application Priority Data
Sep. 30, 2011 (KR) 10-2011-0100186
Feb. 13, 2012 (KR) 10-2012-0014138

(51) Int. Cl. H01L 29/02; H01L 21/762

(52) U.S. Cl. 257/632; 438/458; 257/E29.002; 257/E21.568

(57) ABSTRACT

Provided are a method of manufacturing a flexible device and a flexible device manufactured thereby.

The method of manufacturing a flexible device according to the present disclosure includes: fabricating a device on an upper silicon layer of a silicon-on-insulator (SOI) substrate comprising a lower silicon layer, an insulation layer and the upper silicon layer stacked sequentially; adhering a second silicon substrate to the upper silicon layer; removing the lower silicon layer; transferring the upper silicon layer with the device fabricated to a flexible substrate using the second silicon substrate; and stacking a passivation layer on the flexible substrate, wherein the device is located at a position of a neutral mechanical plane of the entire device as the passivation layer is stacked.

### TECHNICAL FIELD

The present disclosure relates to a method of manufacturing a flexible device and a flexible device manufactured thereby. More particularly, it relates to a method of manufacturing a flexible device enabling manufacturing of a large area device with superior alignment on a flexible substrate in an economical way and a flexible device manufactured thereby.

### BACKGROUND ART

Very-large-scale integration (VLSI) devices are integrated circuits (ICs) improved from large-scale integration (LSI) devices to allow for smaller and lighter electronic circuit components.

In general, a VLSI device is manufactured by fabricating a number of light and compact electronic devices such as transistors and capacitors on a silicon substrate. Especially, since the device is manufactured by a semiconductor process accompanied by high temperatures or harsh conditions, the VLSI has been manufactured only on hard substrates such as the silicon substrate.

However, because of the limitation of the hard, silicon substrate, the application of the VLSI device has been limited.

Meanwhile, needs on flexible electronic devices that can be conveniently used in various daily lives are increasing. Thus, researches for realizing flexible devices are being conducted in various fields. In 2004, a printable microstructure semiconductor (μs-Sc) was invented by the Illinois Institute of Technology (Appl. Phys. Lett. 84, 5398, 2004, prior art 1).

In the prior art 1, single crystalline silicon having superior device performance is taken directly off from a bulk silicon substrate to obtain a microstructure semiconductor, which is then transferred onto a flexible substrate using a soft lithography technique. The device manufactured by transferring the single crystalline microstructure semiconductor onto the plastic substrate exhibits the most excellent electrical performance (effective mobility>500 cm²N·s) among the existing flexible electronic devices (IEEE Electron Device Lett., 27, 460, 2006).

To describe the prior art 1 in more detail, the microstructure semiconductor is designed to have a dumbbell shape and its lower portion is etched to form a support shaft. The microstructure semiconductor is then taken off using a patterned PDMS stamp to selectively transfer only the microstructure semiconductor of a desired position. According to the prior art 1, not only a device can be manufactured on a desired position of the plastic substrate through the selective transferring but also the microstructure semiconductor remaining on a silicon-on-insulator (SOI) substrate without being transferred can be transferred later onto a desired position. As a result, the manufacturing cost can be saved. However, when the microstructure semiconductor is selectively transferred, because the patterned PDMS stamp is used, a sagging effect in which a recessed portion is collapsed due to the intrinsic properties of PDMS may occur, thus resulting in unwanted separation of the microstructure semiconductor. In addition, when the microstructure semiconductor is transferred, contract or relaxation of the PDMS may occur. As a result, it is difficult to precisely align the microstructure semiconductor and the PDMS stamp on the silicon substrate. Furthermore, there is limitation in manufacturing a large area device since the penetration of an etchant is restricted.

An implantable neuroprosthetic device is a device attached to or implanted in the body for recovering or alleviating sensory and motor disorders caused by congenital or acquired nerve damage and many related technologies have been actively studied. The implantable neuroprosthetic device consists of various components, among which the integrated circuit is very important in enabling nerve stimulation, neural signal processing, biomedical communication, or the like. However, since the existing integrated circuit used in the implantable neuroprosthetic device is a hard and large-sized chip, it is a big obstacle to the implantation of the neuroprosthetic device.

### DISCLOSURE

### Technical Problem

The present disclosure is directed to providing a novel method of manufacturing a flexible device.

The present disclosure is also directed to providing a flexible device manufactured by the method.

The present disclosure is also directed to providing a thin and flexible integrated circuit for an implantable neuroprosthetic device.

### Technical Solution

In one general aspect, the present disclosure provides a method of manufacturing a flexible device comprising: fabricating a device on an upper silicon layer of a silicon-on-insulator (SOI) substrate comprising a lower silicon layer, an insulation layer and the upper silicon layer stacked sequentially; adhering a second silicon substrate to the upper silicon layer; removing the lower silicon layer; transferring the upper silicon layer with the device fabricated to a flexible substrate using the second silicon substrate; and stacking a passivation layer on the flexible substrate, wherein the device is located at a position of a neutral mechanical plane of the entire device as the passivation layer is stacked.

In another general aspect, the present disclosure provides a method of manufacturing a flexible device comprising: fabricating a device on an upper silicon layer of an SOI substrate comprising a lower silicon layer, an insulation layer and the upper silicon layer stacked sequentially; forming an adhesion layer on the upper silicon layer; adhering the upper silicon layer to a second silicon substrate using the adhesion layer; removing the lower silicon layer; transferring the upper silicon layer with the device fabricated to a flexible substrate using the second silicon substrate; and stacking a passivation layer on the flexible substrate, wherein the device is located at a position of a neutral mechanical plane of the entire device as the passivation layer is stacked.

In another general aspect, the present disclosure provides a flexible device comprising: a flexible substrate; a device provided on the flexible substrate; and a passivation layer formed on the device, wherein the device is located at a position of a neutral mechanical plane of the entire device.

### Advantageous Effects

The method of manufacturing a flexible device according to the present disclosure enables manufacturing of a large area device with superior alignment on a flexible substrate in an economical way. In addition, since the flexible device manufactured according to the present disclosure is fabricated on a silicon substrate and then adhered to a flexible substrate, limitation of manufacturing process can be avoided. Furthermore, the superior alignment of the device can be maintained also on the flexible substrate.

According to the present disclosure, an implantable neuroprosthetic device with small size and improved flexibility can be manufactured to enable easier implantation.

### DESCRIPTION OF DRAWINGS

FIGS. 1-6 illustrate a method of manufacturing a flexible device according to an exemplary embodiment of the present disclosure.

FIGS. 7-14 illustrate a method of manufacturing a flexible device according to another exemplary embodiment of the present disclosure.

FIGS. 15-19 illustrate transfer of a unit device to a plastic substrate.

FIGS. 20 and 21 respectively show photographic images of a device manufactured on an SOI substrate before and after transfer.

FIGS. 22 and 23 show a nanotransistor structure fabricated according to the present disclosure and an optical microscopic image thereof.

FIGS. 24 and 25 respectively show the result of testing characteristics (I-V curve) of a transistor device before and after transfer.

FIGS. 26 and 27 show the result of testing characteristics of a transistor device with a polymer layer of FIG. 19 stacked before and after transfer.

FIG. 28 shows change in characteristics of a transistor and an IC caused by bending.

FIG. 29 shows the result of observing electrical characteristics of a nanotransistor under mechanical strain and fatigue conditions.

FIG. 30 shows an equivalent circuit of an integrated circuit (RF switch). The RF switch is an on/off switch determining whether an external RF signal will be allowed to be inputted into an electronic device.

FIG. 31 shows characteristics of an integrated circuit (RF switch) after transfer.

FIG. 32 shows characteristics of an integrated circuit (RF switch) after transfer.

FIGS. 33-36 illustrate a process of transferring a device which is fabricating on an SOI substrate and is given flexible characteristics by removing a lower silicon layer onto a liquid-crystal polymer (LCP, 800) and then encapsulating with an LCP.

FIG. 37 shows a schematic diagram and a photographic image of the LCP-based flexible device manufactured in FIG. 26.

FIG. 38 is a photographic image illustrating a monolithic LCP process for biomedical implantation.

FIGS. 39 and 40 illustrate biomedical applicability of a flexible device manufactured according to the present disclosure.

FIG. 41 shows an example wherein a flexible device according to the present disclosure is used in an optical device such as an OLED.

### MODE FOR INVENTION

Hereinafter, the embodiments of the present disclosure will be described in detail with reference to accompanying drawings. The following embodiments are provided as examples so that the scope of the present disclosure will be fully conveyed to those skilled in the art. Accordingly, the present disclosure may be embodied in different forms without being limited to the embodiments described below. In the appended drawings, the width, length, thickness, etc. of elements may be somewhat exaggerated. Throughout the specification, the same reference numerals refer to the same or equivalent parts. Most of the appended drawings are plan views or partial cross-sectional views (along lines A-A′, B-B′ or C-C′). The term “flexible” is used to distinguish from a substrate having hard (rigid) properties such as a silicon substrate. It encompasses bendable or foldable characteristics of a substrate such as a plastic substrate.

In particular, the method of manufacturing a flexible device according to the present disclosure makes it possible to manufacture a nanodevice of sub-micrometer scale, e.g. a nanotransistor, on a flexible substrate with superior alignment. In addition, a flexible integrated circuit (IC) or a very-large-scale integration (VLSI) devices with a number of devices connected to each other in circuitry can be manufactured by fabricating first on a silicon substrate and then transferring to a flexible substrate. Furthermore, mechanical and electrical characteristics of a device are improved by using a neutral mechanical plane.

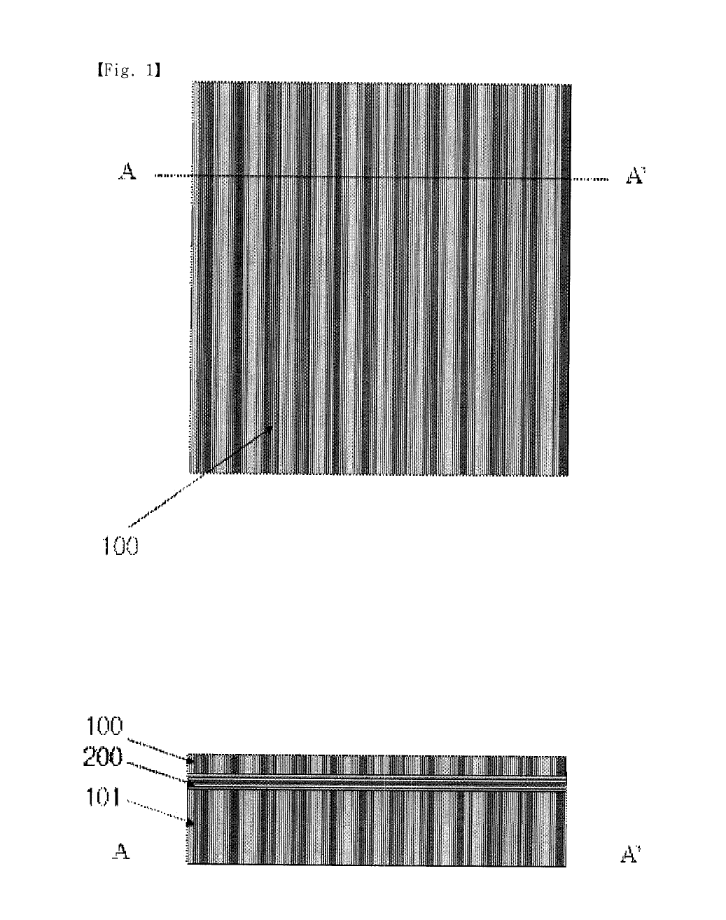

FIGS. 1-6 illustrate a method of manufacturing a flexible device according to an exemplary embodiment of the present disclosure.

FIG. 1 shows a silicon-on-insulator (SOD substrate having an insulation layer (silicon oxide layer, 200) which is a buffer layer formed between silicon substrates. In the present disclosure, an upper silicon layer (second silicon substrate, 100) and a lower silicon layer (first silicon substrate, 101) of the SOI substrate may be separated with the buffer layer (200) therebetween. In particular, the upper silicon layer (100) may have a small thickness to provide flexible characteristics.

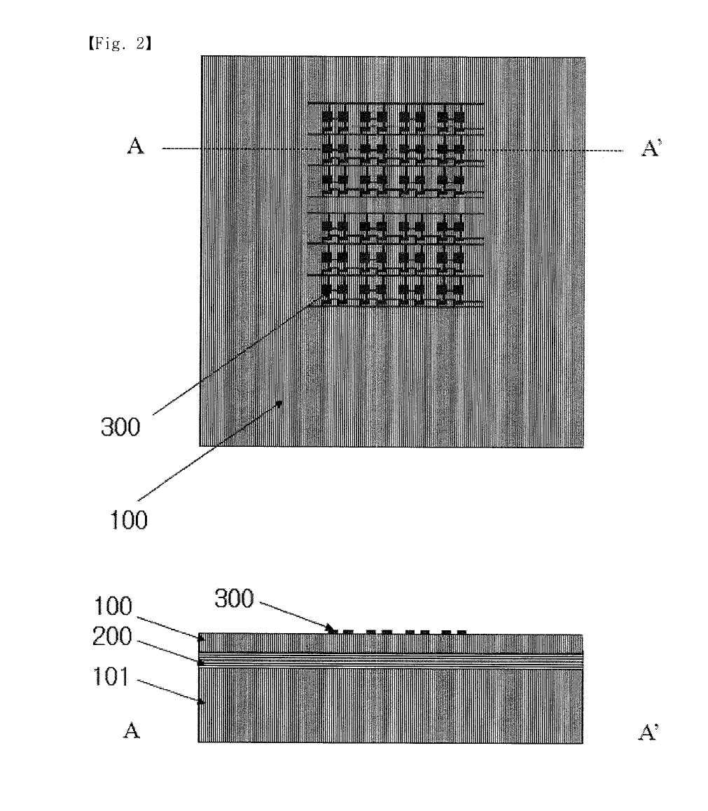

Referring to FIG. 2, a device (300) such as a transistor is fabricated on the silicon substrate, particularly on the upper silicon layer (100) according to a commonly employed method. Since the fabrication is conducted on the silicon substrate having superior chemical and thermal resistance, the device can be fabricated according to a commonly employed semiconductor manufacturing process. Although the device may be a transistor in an exemplary embodiment of the present disclosure, it is not limited thereto.

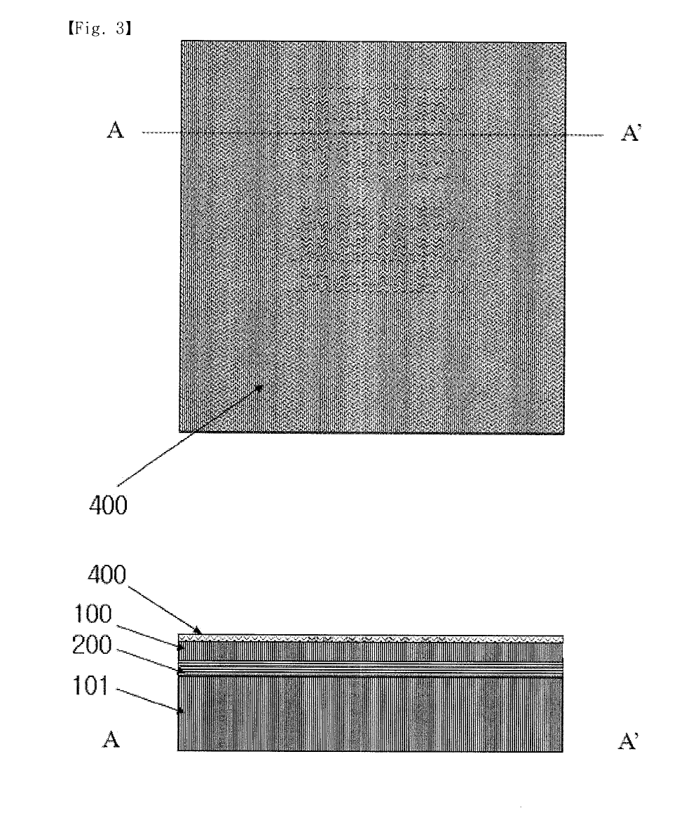

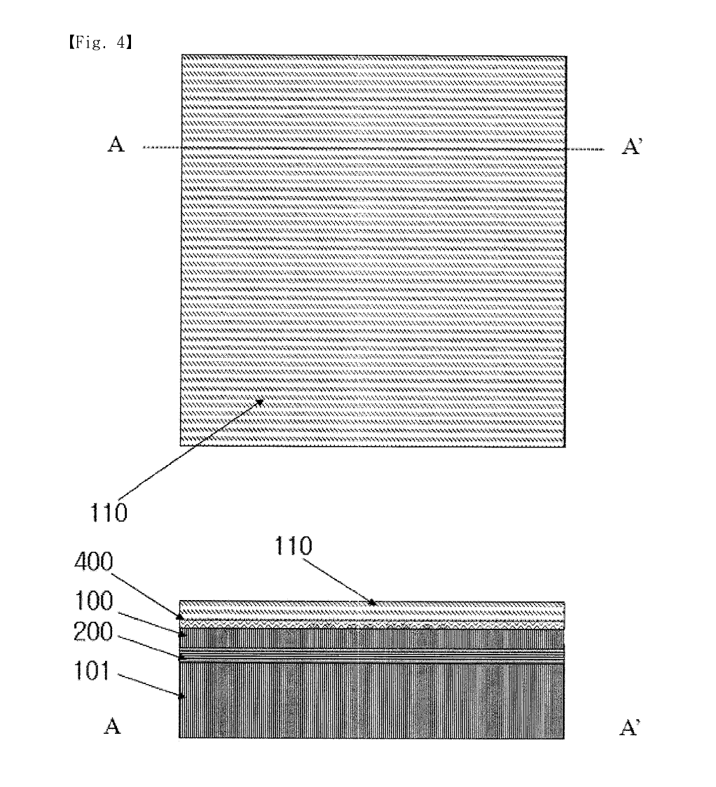

Referring to FIG. 3, a first adhesion layer (400) is formed on the silicon substrate with the device (300) fabricated. Then, referring to FIG. 4, a second silicon substrate (110) is adhered to the SOI substrate by the first adhesion layer (400). In an exemplary embodiment of the present disclosure, the first adhesion layer (400) serves to adhere the upper silicon layer (100) of the SOI substrate with the second silicon substrate (110) provided thereabove. In an exemplary embodiment of the present disclosure, the first adhesion layer (400) may be one that has good adhesivity to silicon and can be easily removed in the following process. An epoxy-based adhesive may be used as the adhesion layer (400) in an exemplary embodiment of the present disclosure, but the scope of the present disclosure is not limited thereto. The second silicon substrate not only protects the device but also temporarily increase the height of the substrate, thus enhancing hardness (rigidity) of the substrate. As a result, the superior alignment of the device can be maintained. If the second silicon substrate (110) is absent, the alignment of the device may become worse because the thickness of the device substrate decreases. This problem becomes severer when the device is a large area device. However, in the present disclosure, it is possible to maintain the superior alignment, which is one of the most difficult problems in manufacturing a flexible device, owing to the second silicon substrate (110) that temporarily increases the height of the substrate.

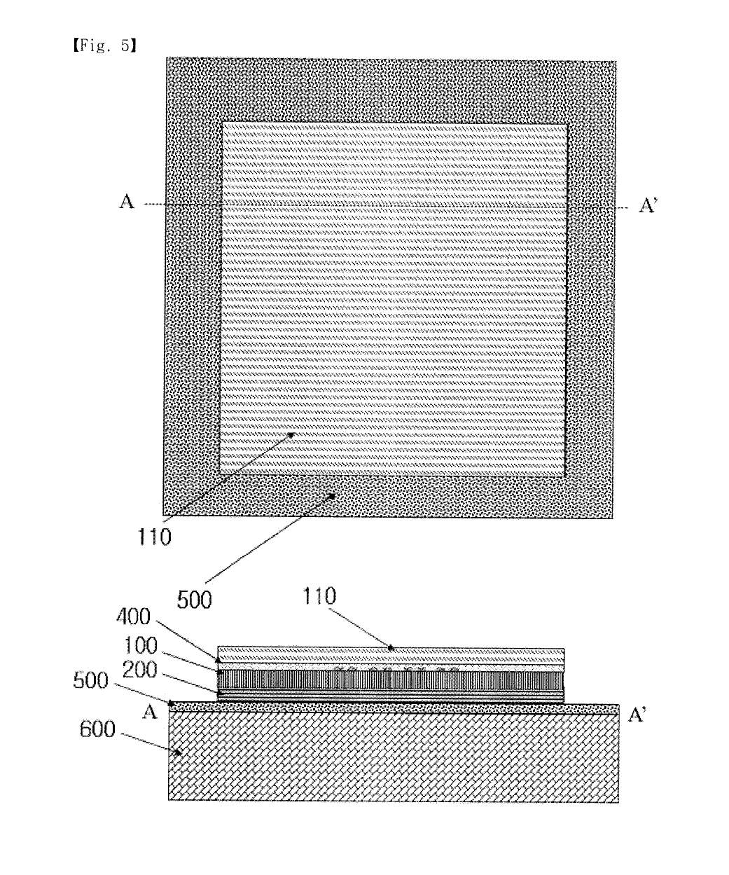

Referring to FIG. 5, after the lower silicon substrate (100) of the SOI substrate is removed, the device layer is transferred to a plastic substrate with a second adhesion layer (500) formed thereon. In an exemplary embodiment of the present disclosure, the lower silicon substrate (101) of the SOI substrate may be removed by a wet etching method. However, dry etching or a mechanical or physical removing method may also be used. During the transfer, the second silicon substrate (110) improves alignment of the device by temporarily increasing the height of the substrate as described above.

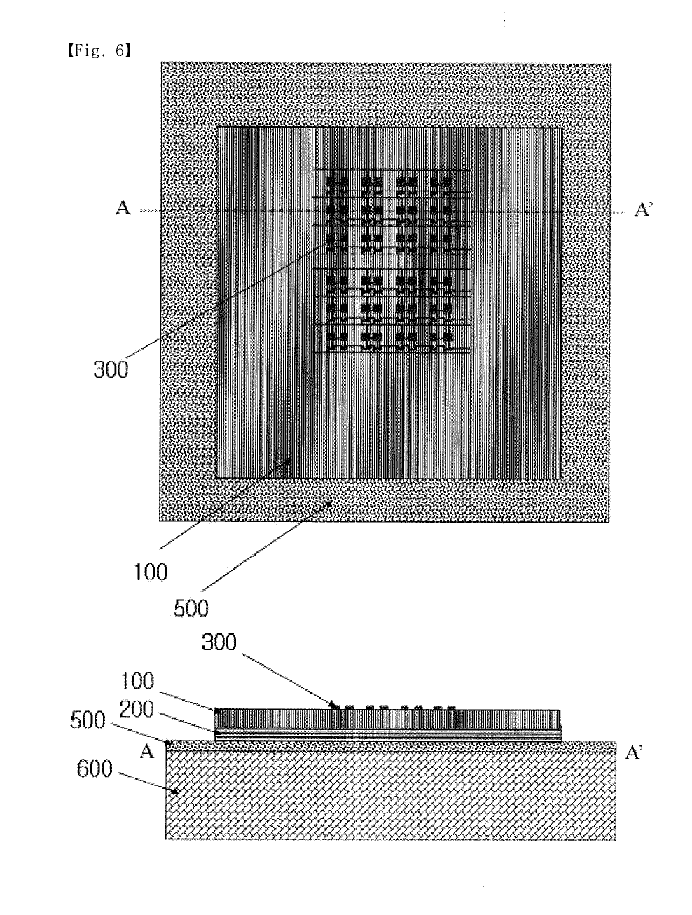

Referring to FIG. 6, the second silicon substrate (110) which is a support layer is removed and, as a result, the device is manufactured on the plastic substrate (600) which is a flexible substrate.

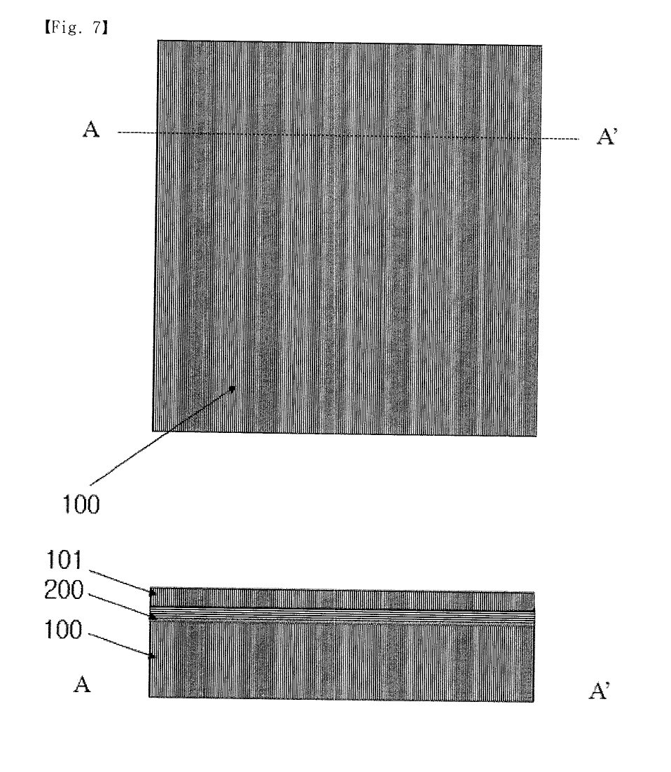

FIGS. 7-14 illustrate a method of manufacturing a flexible device according to another exemplary embodiment of the present disclosure.

Referring to FIG. 7, an SOI substrate with the same configuration as that of FIG. 1 is provided.

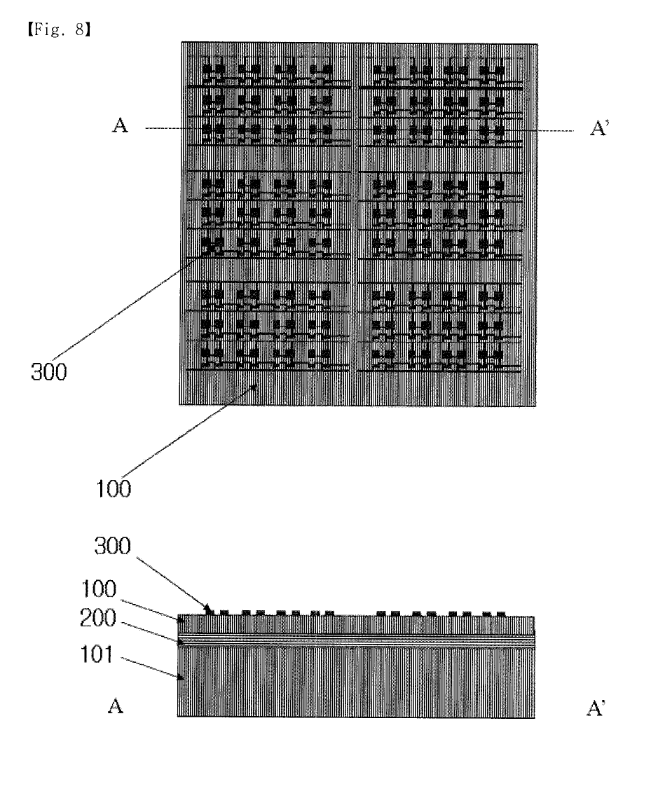

Referring to FIG. 8, one or more device is fabricated on the SOI substrate according to an existing semiconductor process.

Referring to FIG. 9, a first adhesion layer (400) is formed on an SOI substrate and a device. The first adhesion layer (400) physically fixes a support layer that will be adhered thereon.

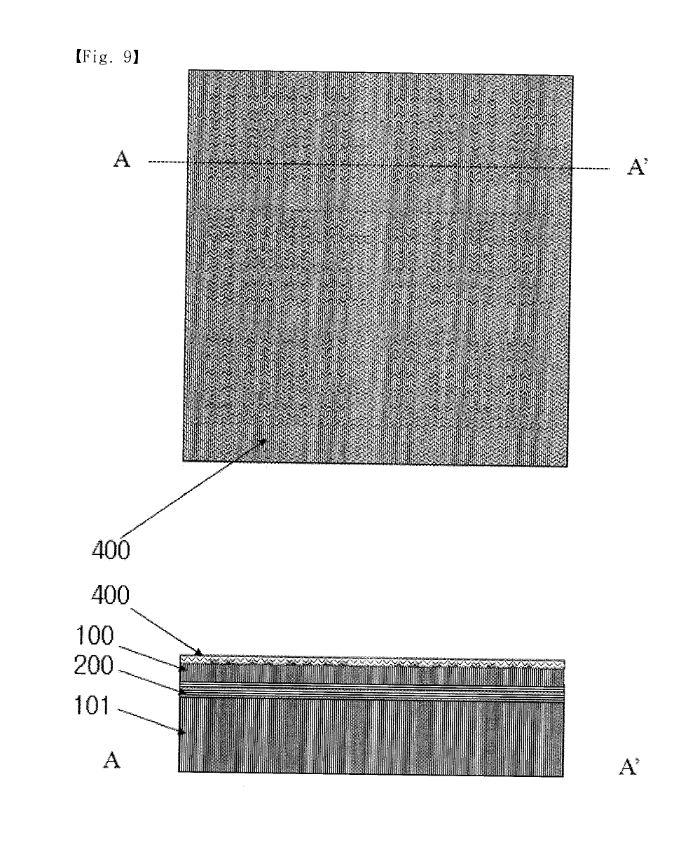

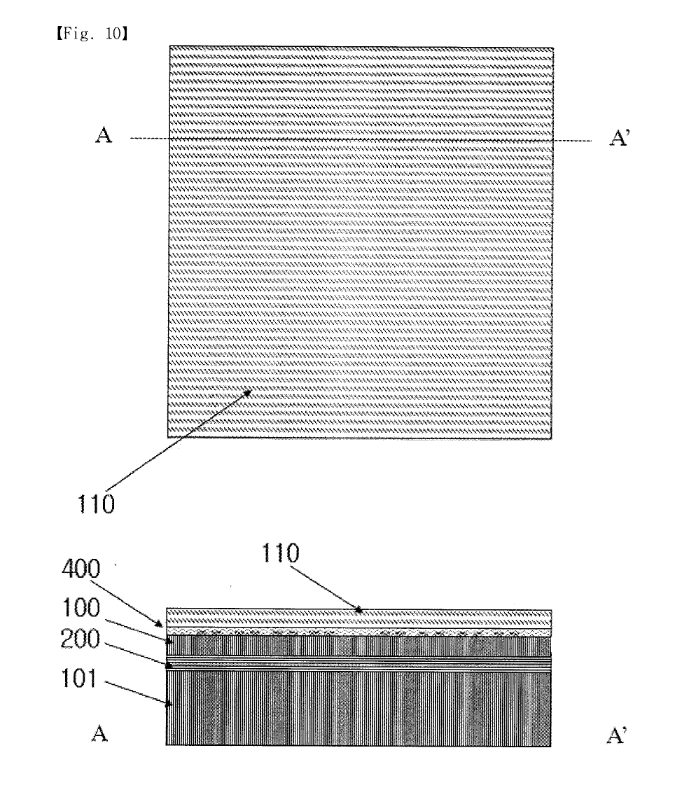

Referring to FIGS. 10 and 11, a second silicon substrate (110) which is a support layer is adhered to the first adhesion layer (400) and a first silicon substrate (100) of the SOI substrate is removed by a physical or chemical method.

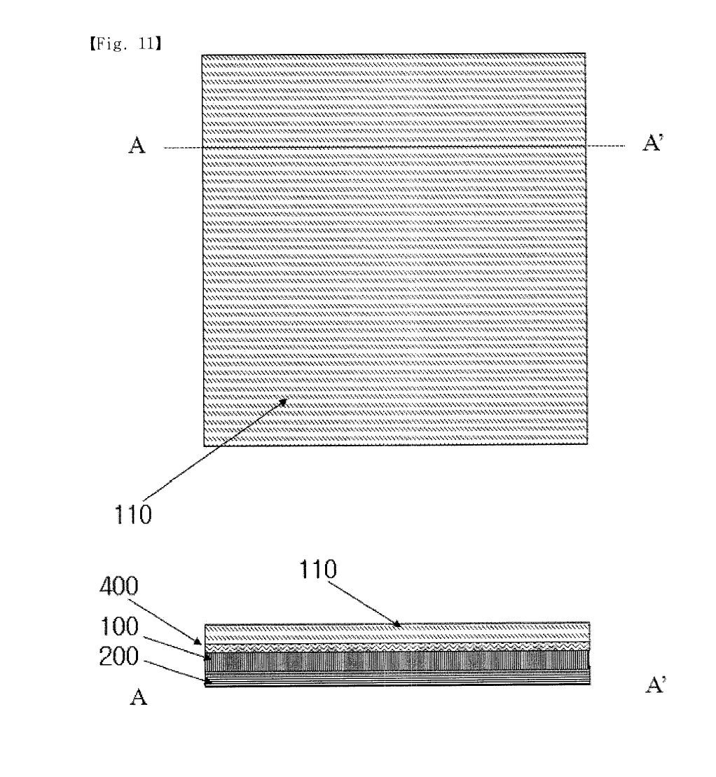

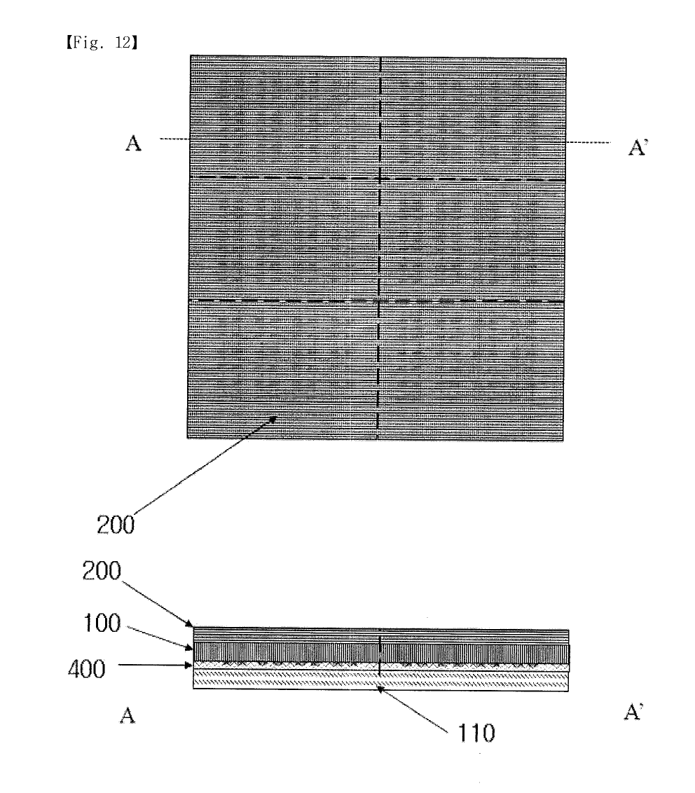

FIG. 12 shows plural unit devices fabricated on a sacrificial substrate (see FIG. 11). The plural unit devices may be separated physically as shown by the broken lines of FIG. 12. That is to say, the devices on the second silicon substrate (110) may be separated into individual units using a cutting means. Accordingly, the devices may be selectively transferred to a plastic substrate.

Referring to FIG. 13, a specific device desired to be transferred among the unit devices is adhered to a plastic substrate (600) on an insulation layer (200) of the SOI substrate. As described earlier, the plastic substrate (600) is adhered by a second adhesion layer (500) formed on the insulation layer (200).

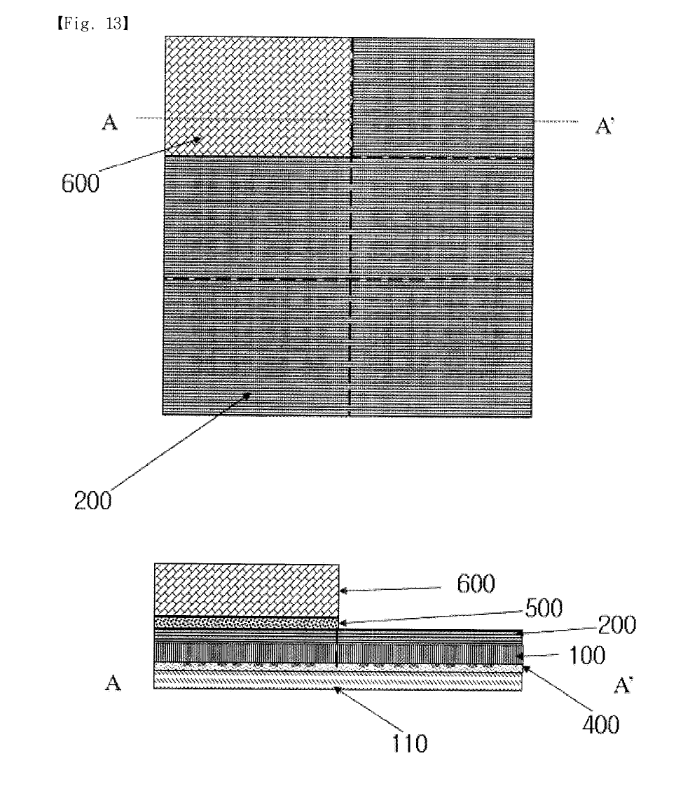

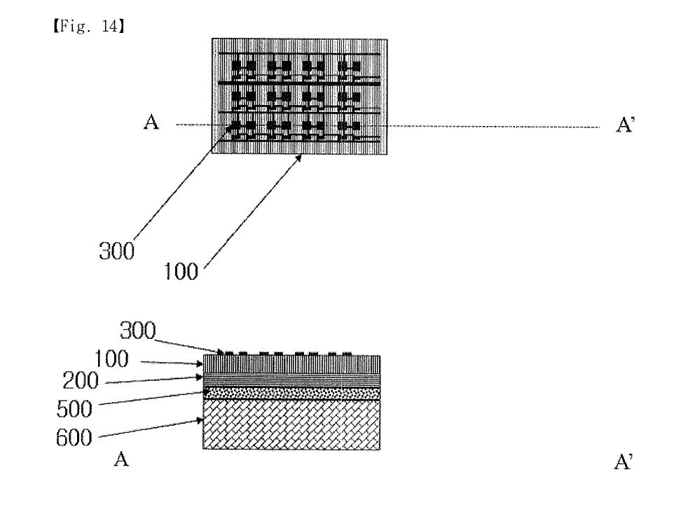

Referring to FIG. 14, selective transfer to the plastic substrate (600) can be achieved by detaching the adhered plastic substrate (600).

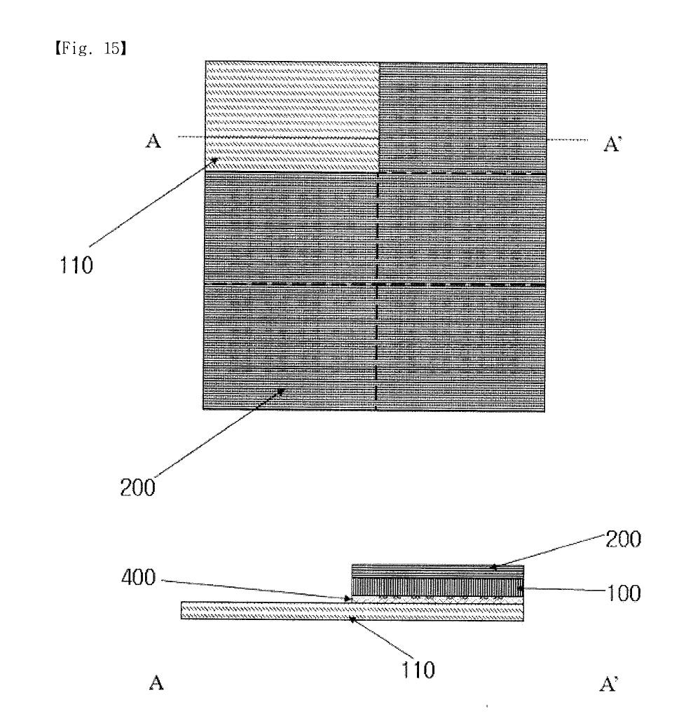

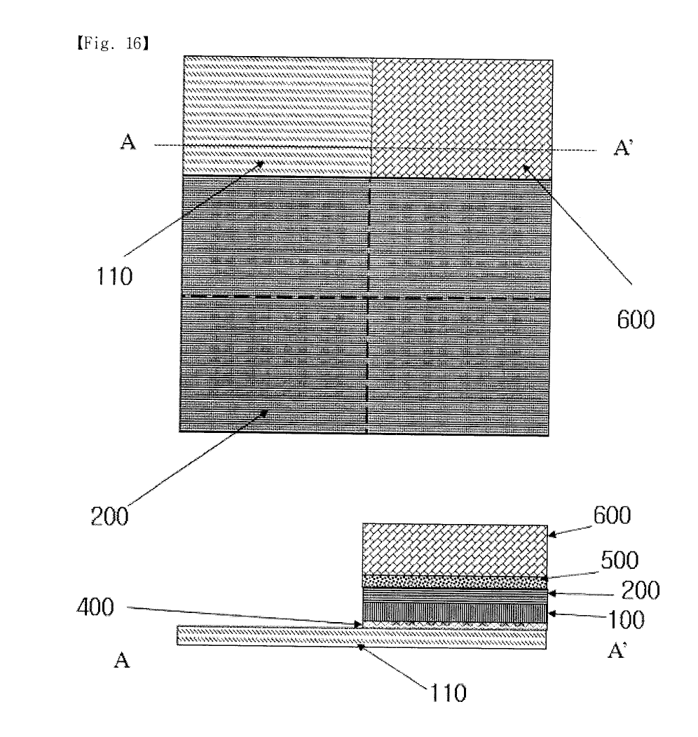

FIGS. 15-18 illustrate transfer of another unit device to the plastic substrate by the same method. In this manner, the devices fabricated on a large area SOI substrate can be selectively transferred to the plastic substrate.

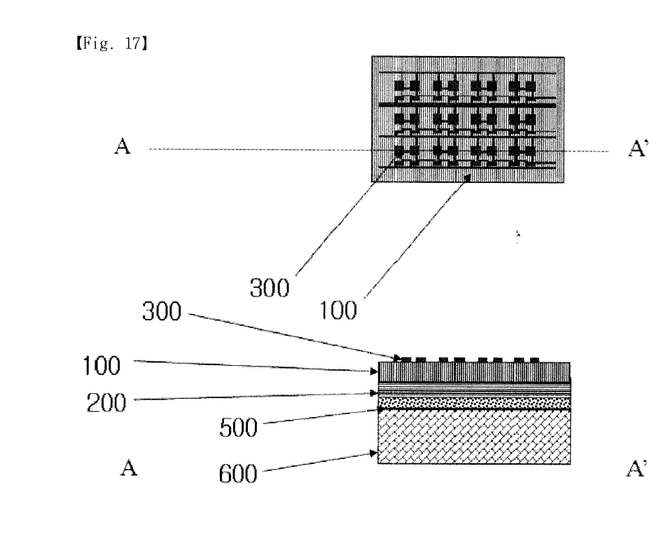

Referring to FIG. 19, a passivation layer (700) is formed on a device transferred to a flexible substrate. As the polymer layer is formed, the device layer of the present disclosure is provided at a neutral mechanical plane of the entire device. In an exemplary embodiment of the present disclosure, as the passivation layer (700) is formed, the device is located at the neutral mechanical plane where compressive stress equals the tensile stress applied from above. That is to say, in the present disclosure, the device comprising a hard inorganic material is provided between flexible polymer materials, thereby improving mechanical stability of the device. Furthermore, electrical characteristics of the device are improved, which will be described in detail later.

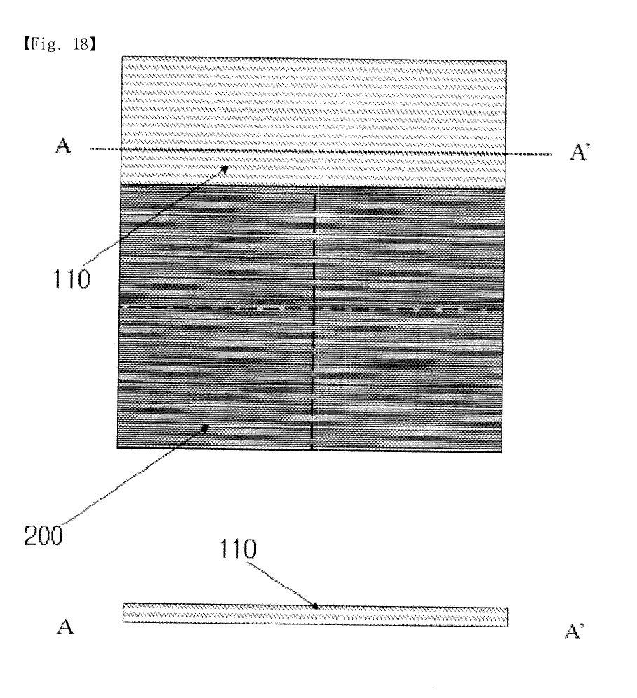

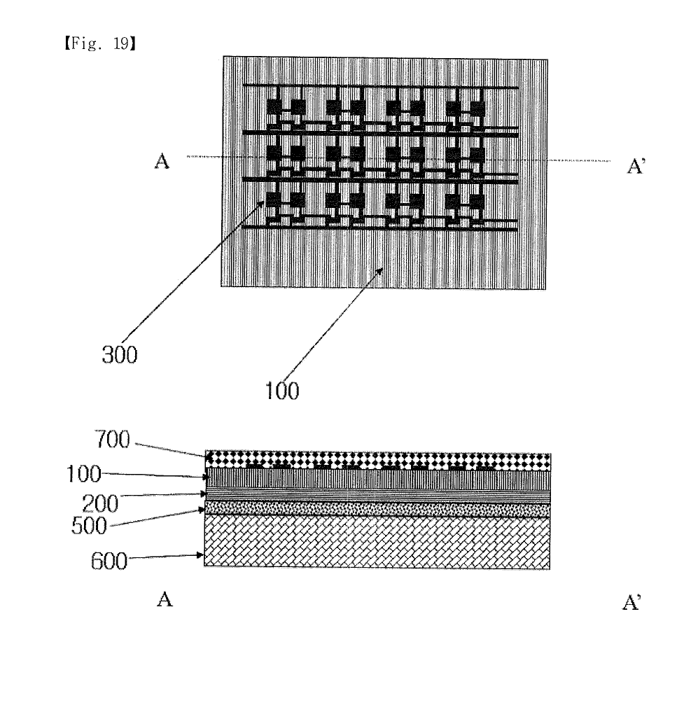

FIGS. 20 and 21 respectively show photographic images of a device manufactured on an SOI substrate before and after transfer.

Referring to FIG. 21, a device transferred to a plastic substrate shows excellent flexible characteristics.

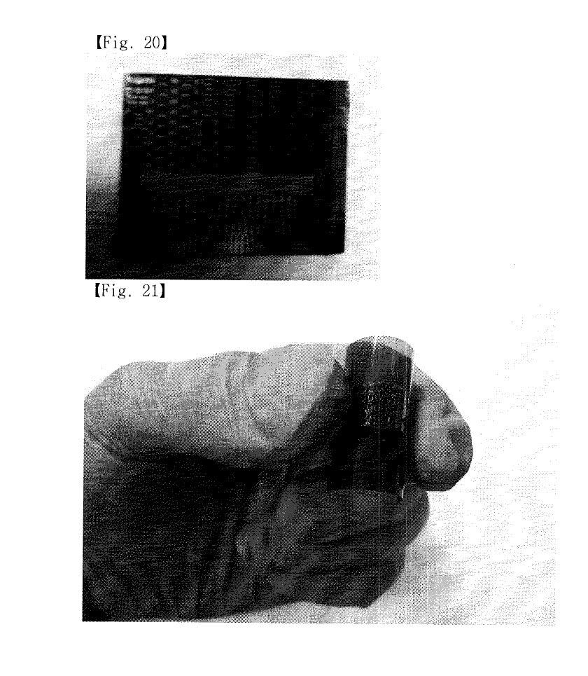

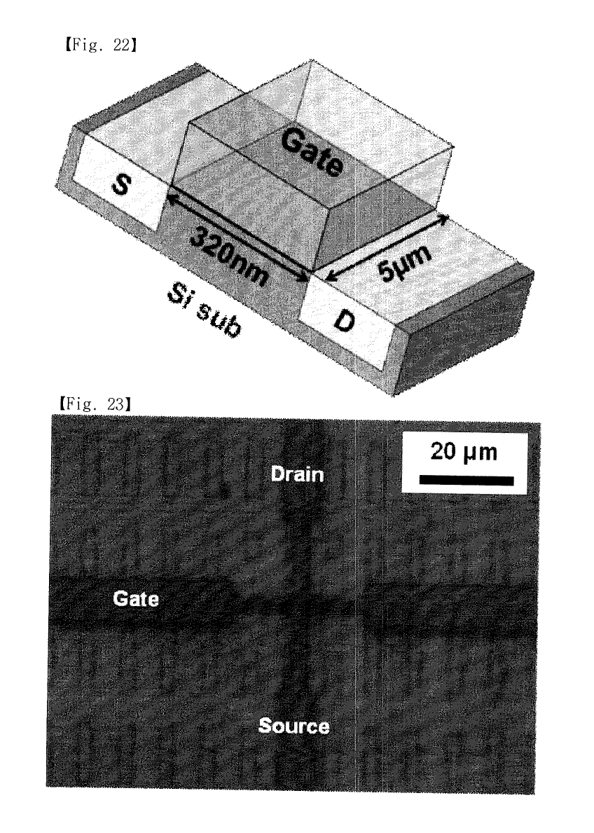

FIGS. 22 and 23 show a nanotransistor structure fabricated according to the present disclosure and an optical microscopic image thereof.

FIGS. 24 and 25 respectively show the result of testing characteristics (I-V curve) of a transistor device before and after transfer.

Referring to FIGS. 24 and 25, after transfer, a transistor without the polymer layer of FIG. 19 shows decrease in electrical current and shift of threshold voltage in the transfer curve.

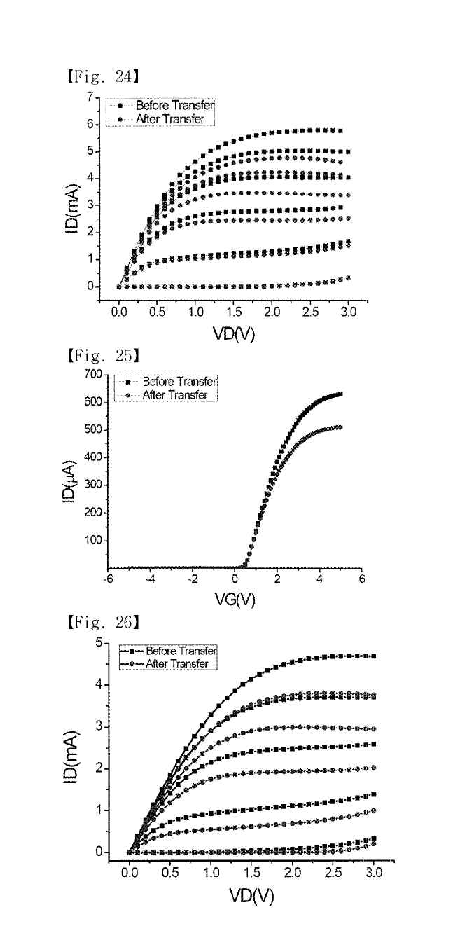

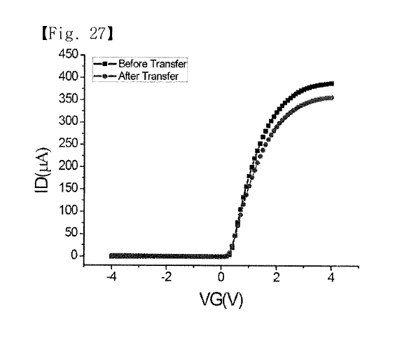

FIGS. 26 and 27 show the result of testing characteristics of a transistor device with a polymer layer of FIG. 19 stacked before and after transfer.

Referring to FIGS. 26 and 27, after transfer, a transistor device with the passivation layer of FIG. 19 (e.g., 15-μm thick SU-8) stacked shows significantly decreased change in characteristics. This suggests that the change in characteristics of the device occurring before and after transfer can be reduced by using the neutral mechanical plane formed in the polymer layer. In addition, if a passivation layer (700) is absent on the VLSI device, the device may be easily damaged by strain and stress after transfer. To prevent this, a passivation layer (700) comprising a ceramic or polymer material is provided on the device.

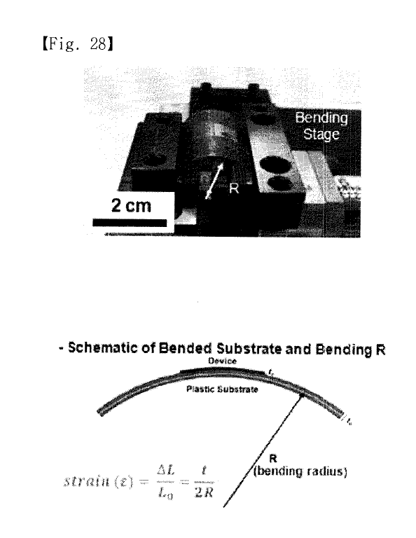

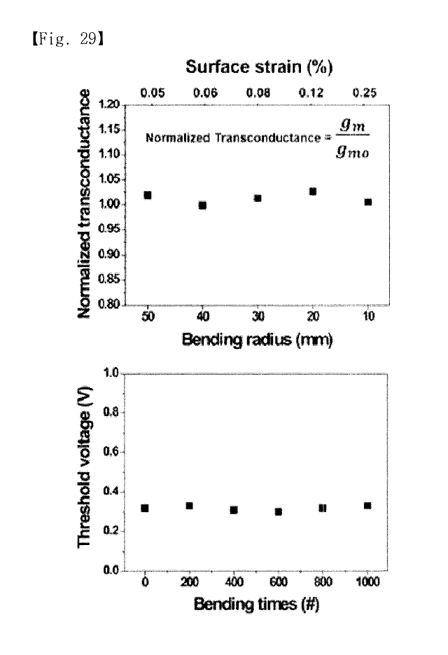

FIG. 28 shows change in characteristics of a transistor and an IC caused by bending.

Referring to FIG. 28, bending test was performed using a bending stage in order to observe change in electrical characteristics of a flexible nanotransistor and an integrated circuit under mechanical strain and fatigue conditions after transfer. Change in electrical characteristics with mechanical strain was observed. Also, change in electrical characteristics with bending times was observed.

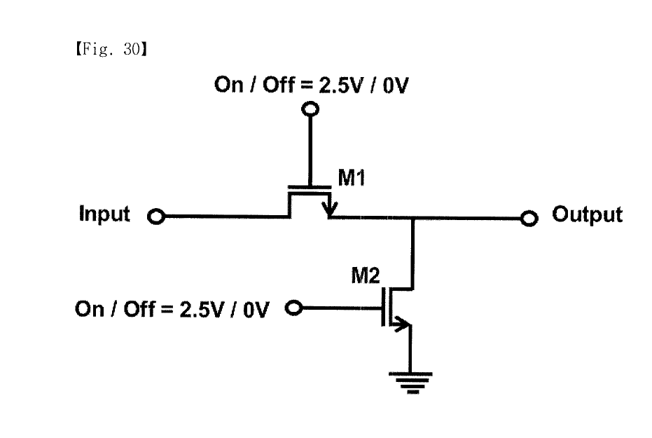

FIG. 29 shows the result of observing the electrical characteristics of the nanotransistor under mechanical strain and fatigue conditions.

FIG. 29 shows change in transconductance of the nanotransistor with mechanical strain. Normalized transconductance is defined as the ratio of the transconductance of the device before and after bending. The change in characteristics of the nanotransistor under fatigue condition was represented as the change in threshold voltage. To conclude, the change in the electrical characteristics of the device under mechanical strain and fatigue conditions was not greater than about 5%, meaning that the device exhibits stable performance.

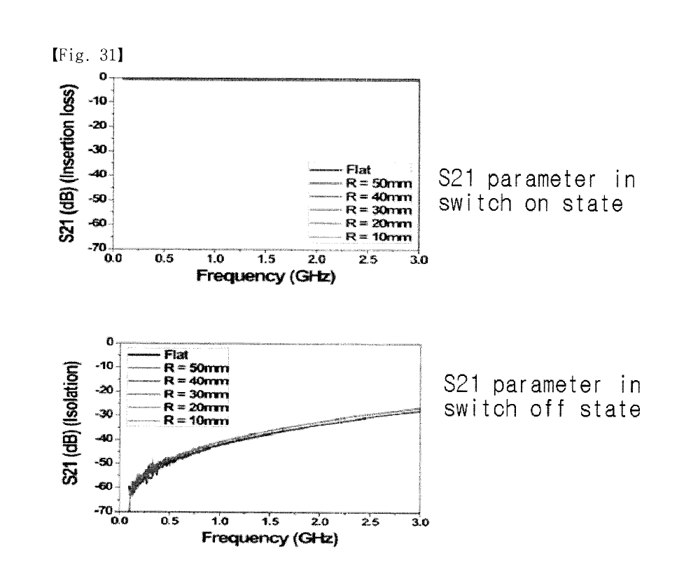

FIG. 30 shows an equivalent circuit of an integrated circuit (RF switch). The RF switch is an on/off switch determining whether an external RF signal will be allowed to be inputted into an electronic device.

FIG. 31 shows characteristics of an integrated circuit (RF switch) after transfer.

Referring to FIG. 31, characteristics of an integrated circuit (RF switch) comprising 40-50 transistors were tested after transfer. It exhibited superior characteristics as well as little change in characteristics after bending (mechanical strain). Accordingly, it can be seen that a flexible integrated circuit can be manufactured on a plastic substrate using the method of the present disclosure and its superior characteristics can be maintained as on an Si substrate.

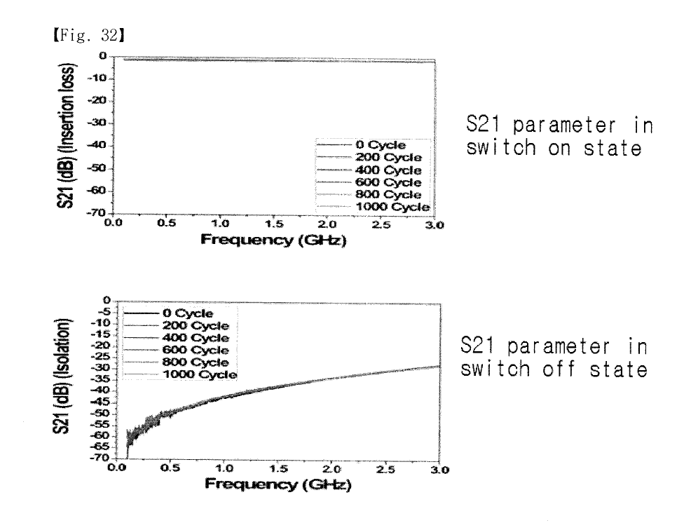

FIG. 32 shows characteristics of an integrated circuit (RF switch) after transfer.

Referring to FIG. 32, change in electrical characteristics of an integrated circuit (RF switch) with bending times was observed (fatigue condition). The device operated stably with little change in electrical characteristics.

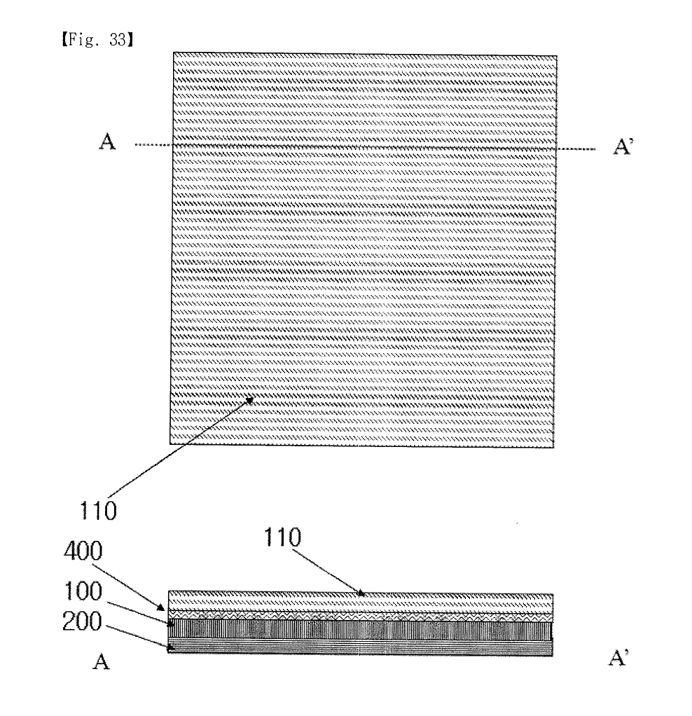

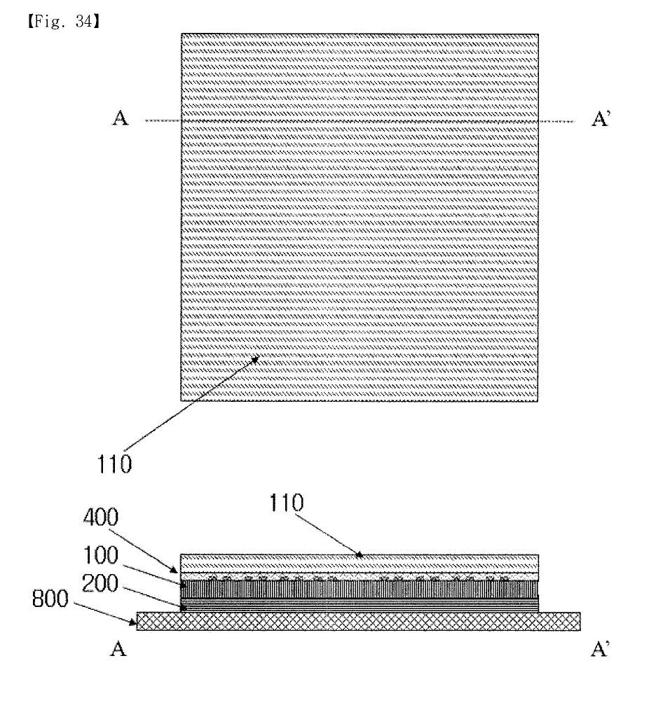

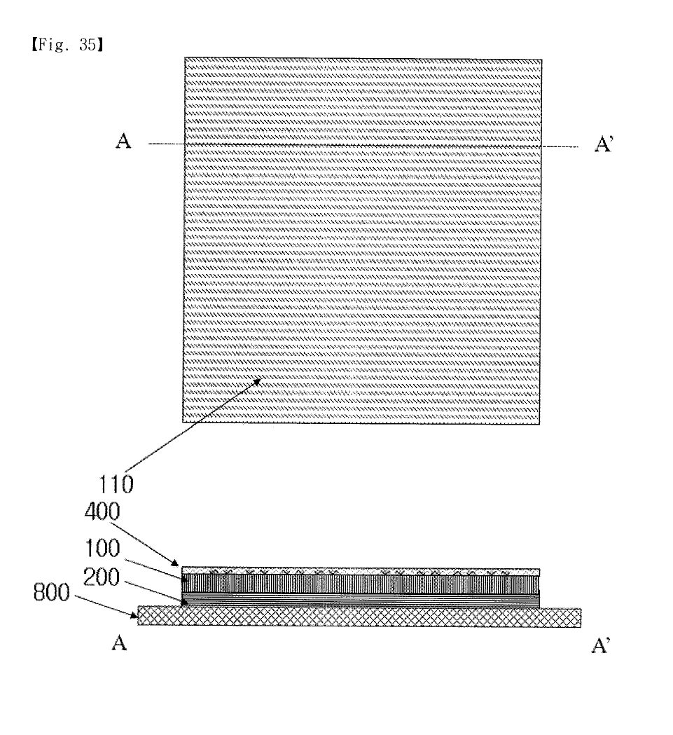

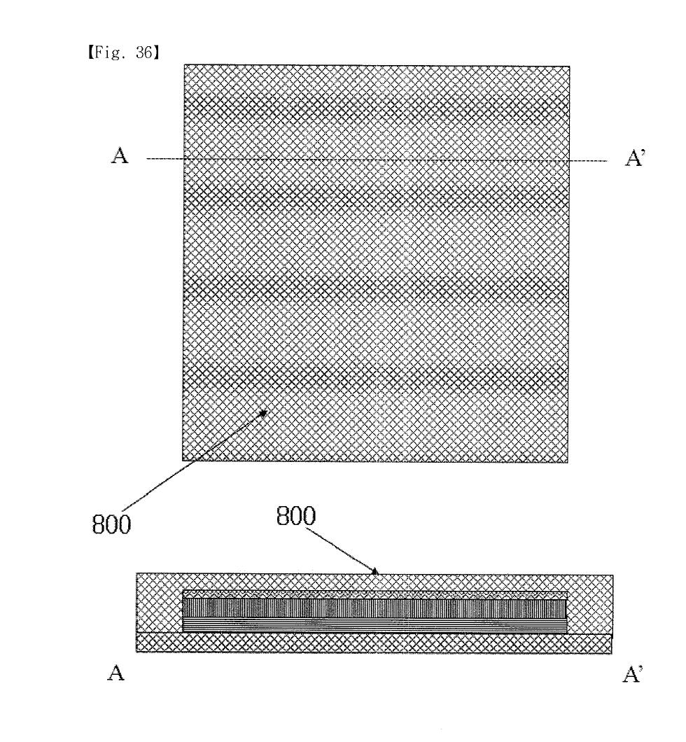

FIGS. 33-36 illustrate a process of transferring a device which is fabricating on an SOI substrate and is given flexible characteristics by removing a lower silicon layer onto a liquid-crystal polymer (LCP, 800) and then encapsulating with an LCP.

According to the present disclosure, the reliability of a device implanted into the body can be improved by completely encapsulating the device with an LCP by a monolithic LCP process. Since the LCP used to protect the device hardly absorbs water, it can protect the device well in the body.

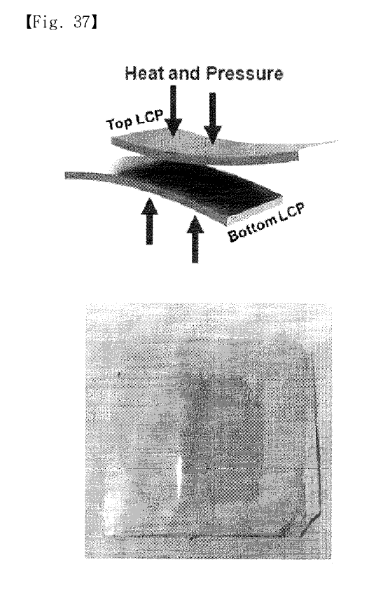

FIG. 37 shows a schematic diagram and a photographic image of the LCP-based flexible device manufactured in FIG. 26.

It can be seen that the LCP-based flexible device of FIG. 37 is suitable for implantation into the body and exhibits good reliability for a long time in the body.

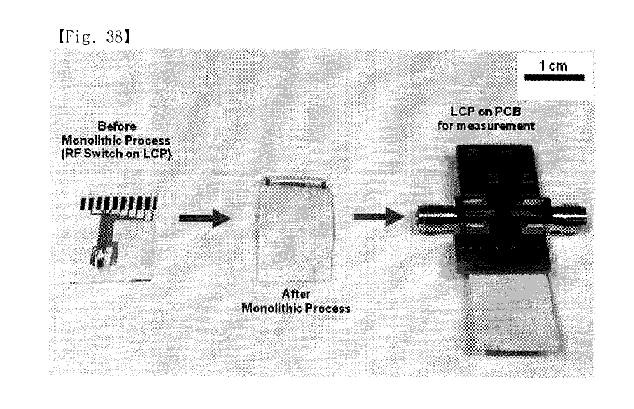

FIG. 38 is a photographic image illustrating a monolithic LCP process for biomedical implantation.

FIG. 38 shows a process of preparing for implantation of an integrated circuit (RF switch) into the body. First, a flexible integrated circuit was manufactured on an LCP substrate and biocompatible packaging was performed by monolithic LCP process. Then, the device was adhered to a PCB for measurement of electrical characteristics.

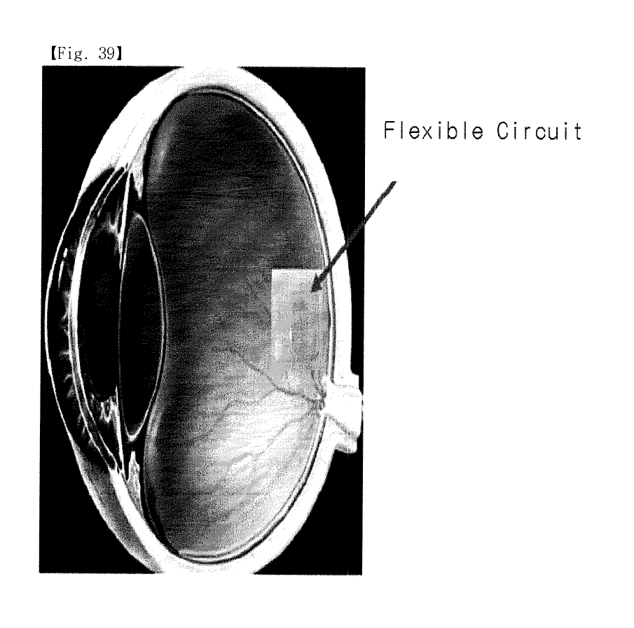

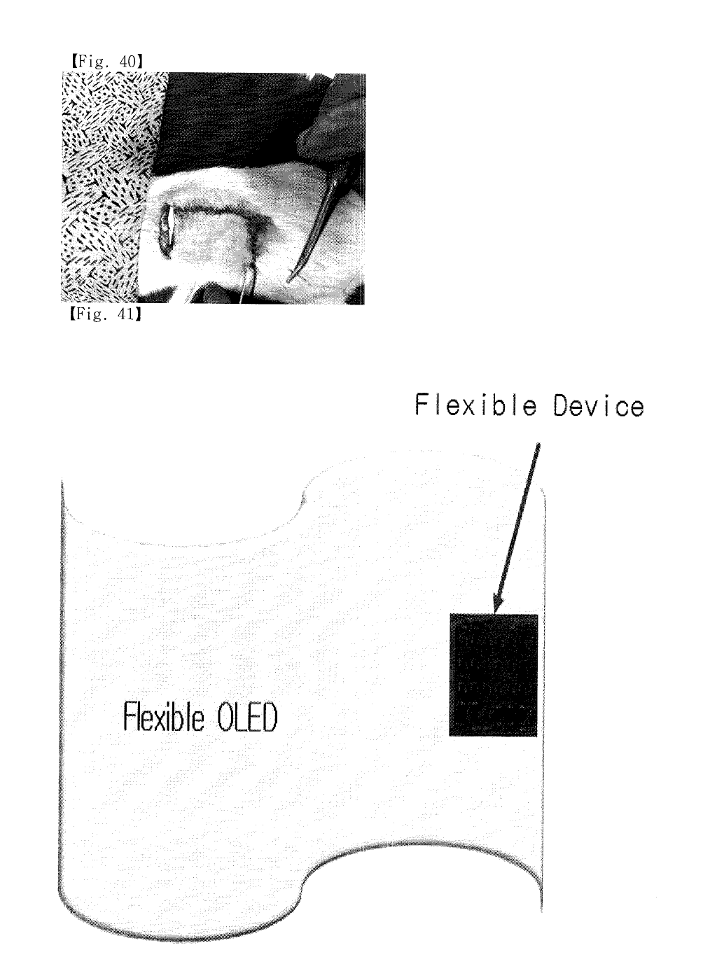

FIGS. 39 and 40 illustrate biomedical applicability of a flexible device manufactured according to the present disclosure.

FIG. 39 shows an artificial retina. The artificial retina requires a circuitry for processing of visual information. The existing artificial retinal circuitry was difficult to be directly inserted into the retina because it was bulky and hard. However, if the transfer technology according to the present disclosure is used, a compact, light and flexible circuitry can be directly attached to the retina.

Referring to FIG. 40, the flexible circuitry device according to the present disclosure can be used for various biological and medical devices operating in vivo. Moreover, the flexible device according to the present disclosure can be used in an optical device such as an OLED as shown in FIG. 41.

Referring to FIG. 41, in the existing flexible OLED, the display portion is flexible but the drive IC that processes data is bulky and hard. In contrast, the method of manufacturing a flexible device according to the present disclosure can provide a fully flexible display device.

Those skilled in the art will appreciate that the conceptions and specific embodiments disclosed in the foregoing description may be readily utilized as a basis for modifying or designing other embodiments for carrying out the same purposes of the present disclosure. Those skilled in the art will also appreciate that such equivalent embodiments do not depart from the spirit and scope of the disclosure as set forth in the appended claims.

1. A method of manufacturing a flexible device comprising:
fabricating a device on an upper silicon layer of a silicon-on-insulator (SOI) substrate comprising a lower silicon layer, an insulation layer and the upper silicon layer stacked sequentially;
adhering a second silicon substrate to the upper silicon layer;
removing the lower silicon layer;
transferring the upper silicon layer with the device fabricated to a flexible substrate using the second silicon substrate; and
stacking a passivation layer on the flexible substrate,
wherein the device is located at a position of a neutral mechanical plane of the entire device as the passivation layer is stacked.

2. The method of manufacturing a flexible device of claim 1, wherein the upper silicon layer and the second silicon substrate are adhered by an adhesion layer formed on the upper silicon layer.

3. The method of manufacturing a flexible device of claim 1, wherein the removal of the lower silicon layer is performed by a wet etching method wherein the lower silicon layer is immersed in an etchant for removing silicon.

4. The method of manufacturing a flexible device of claim 1, which further comprises, after the transfer, removing the second silicon substrate.

5. The method of manufacturing a flexible device of claim 1, wherein the passivation layer comprises a polymer or ceramic material.

6. The method of manufacturing a flexible device of claim 1, wherein the flexible substrate is a liquid-crystal polymer (LCP) substrate.

7. A method of manufacturing a flexible device comprising:
fabricating a device on an upper silicon layer of a silicon-on-insulator (SOI) substrate comprising a lower silicon layer, an insulation layer and the upper silicon layer stacked sequentially;
forming an adhesion layer on the upper silicon layer;
adhering the upper silicon layer to a second silicon substrate using the adhesion layer;
removing the lower silicon layer;
transferring the upper silicon layer with the device fabricated to a flexible substrate using the second silicon substrate; and
stacking a passivation layer on the flexible substrate,
wherein the device is located at a position of a neutral mechanical plane of the entire device as the passivation layer is stacked.

8. The method of manufacturing a flexible device of claim 7, wherein the device fabricated on the SOI substrate is plural in number and the plural devices are separated mechanically.

9. The method of manufacturing a flexible device of claim 7, wherein the passivation layer comprises a polymer or ceramic material.

10. A flexible device comprising:
a flexible substrate;
a device provided on the flexible substrate; and
a passivation layer formed on the device,
wherein the device is located at a position of a neutral mechanical plane of the entire device.

11. The flexible device of claim 10, which is manufactured by the method of claim 1 and is formed on an insulation layer-upper silicon layer of a silicon-on-insulator (SOI) substrate.

12. The flexible device of claim 10, wherein the flexible substrate and the passivation layer comprise a liquid-crystal polymer (LCP) and the device is inserted into the LCP for use as an integrated circuit of an implantable neuroprosthetic device.

13. A display device comprising the flexible device of claim 12
